(19) United States
(12) Patent Application Publication
(10) Pub. No.: US 2017/0213930 A1
(43) Pub. Date: Jul. 27, 2017

(54) MATERIAL FOR PHOTO-ELECTRIC CONVERSION, AND PHOTO-ELECTRIC CONVERTER PROVIDED THEREWITH

(71) Applicant: DSS INTERNATIONAL LLC, Bay Harbor Islands, FL (US)

(72) Inventors: ALEXANDER BRONSHTEIN, BEER-SHEVA (IL); MICHAEL MALINKOVICH, BEER SHEVA (IL); MICHAEL MEJIBOVSKI, MODllN ISRAEL (IL)

(73) Assignee: DSS INTERNATIONAL LLC, Bay Harbor Islands, FL (US)

(21) Appl. No.: 15/006,792

(22) Filed: Jan. 26, 2016

(51) Int. Cl. H01L 31/074; H01L 31/036

(52) U.S. Cl. CPC H01L 31/074; H01L 31/036

(57) ABSTRACT

A material for photo-electric conversion has a multi-layered diamond-like film including an upper layer possessing electrical conductivity of one type and a lower layer possessing electrical conductivity of another different type, and a photo-electric converter is provided with this material and converts light into electric current.

### BACKGROUND OF THE INVENTION

The present invention relates to a material for photo-electric conversion and to a photo-electric converter provided therewith.

Photo-electric converters are known in the art. They are used for example for conversion of solar energy into electrical energy and subsequent use of the thusly produced electric energy for various applications. Such photoelectric converters are used for example as solar batteries which constitute a source of energy for spaceships.

The known photo-electric converters have not found a wide use because they are relatively expensive and also the conversion ratio achieved by the known photoelectric converters is not sufficiently high. Therefore it is advantageous to develop more efficient materials for photo-electric conversion, which as a result can be used to make less expensive and more efficient photo-electric converters.

### BACKGROUND OF THE INVENTION

Accordingly, it is an object of the present invention to provide more efficient materials for photo-electric conversion, and less expensive and more efficient photo-electric converters provided with such material for photo-electric conversion.

In keeping with these objects and with others which will become apparent hereinafter, one feature of the present invention resides, briefly stated, in a material for photo-electric conversion, which is formed as a multi-layered film including a first layer possessing electrical conductivity of one type and a second layer possessing electrical conductivity of another different type.

A further feature of the present invention is that the one layer of the multi-layered film is formed so that the first layer of the multi-layered film is formed so as possess electrical conductivity of n-type and the second layer of the multi-layered film is formed so as to possess electrical conductivity of p-type.

A further feature of the present invention resides in that the material for photo-electric conversion has a substrate located under the layers of the multi-layered film and supporting the latter.

A still further feature of the present invention resides in that the first layer of the multi-layered film which possesses electrical conductivity of n-type is composed of silicon with admixture of chrome, while the second layer of the multi-layered film which possesses electrical conductivity of p-type is composed of silicon with admixture of tungsten.

A further feature of the present invention resides in a photo-electric converter which is provided with a material for photo-electric conversion, formed as a multi-layered film including a first layer possessing electrical conductivity of one type and a second layer possessing electrical conductivity of another different type.

A further feature of the present invention is that the first layer of the multi-layered film is formed so as possess electrical conductivity of n-type and the second layer of the multi-layered film is formed so as to possess electrical conductivity of p-type.

A further feature of the present invention is that the photo-electric convertor is arranged so that the first layer is an upper layer having an upper surface exposed to a source of light, the second layer is a lower layer arranged under the first layer, and the substrate is located under the second layer, with two electrical contacts electrically connected with the first and second layers.

The novel features of the present invention are set forth in particular in the appended claims.

The invention itself will be best understood from the following description of the preferred embodiments which is accompanied by the following drawings.

### BRIEF DESCRIPTION OF THE DRAWINGS

FIG. 1 of the drawings is a view schematically showing a cross section of a material for photo-electric conversion according to the present invention;

FIG. 2 of the drawings is a view schematically showing a photo-electric converter for photo-electric conversion according to the present invention;

FIG. 3 is a view showing a method of manufacturing of a photo-electric convertor according to the present invention.

### DESCRIPTION OF THE PREFERRED EMBODIMENTS

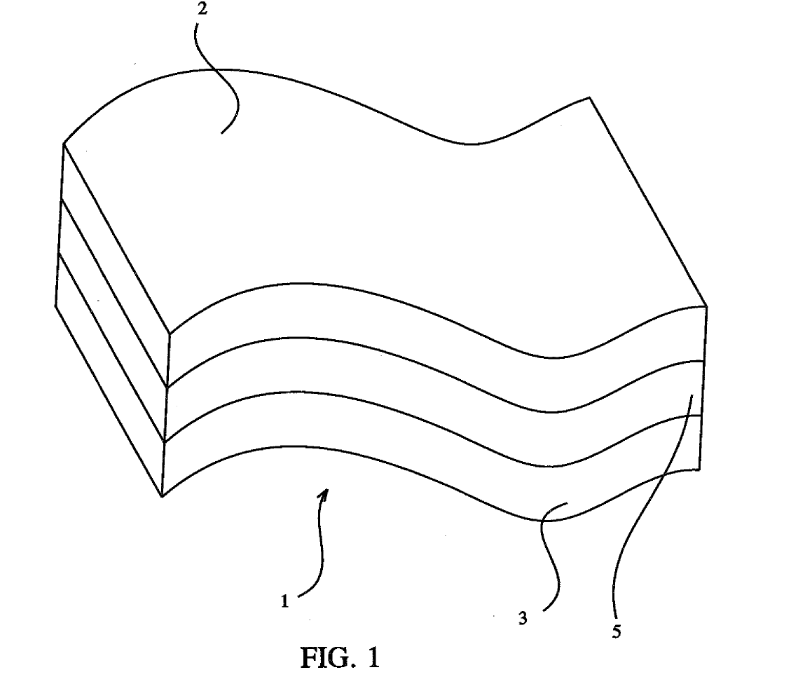

FIG. 1 schematically shows in a material for photo-electric conversion of the present invention. The material for photo-electric conversion according to the present invention is formed as a multi-layered film 1. The multi-layered film 1 includes an upper layer 2 possessing electrical conductivity of one type and a lower layer 3 possessing electrical conductivity of another different type.

The upper layer 2 of the multi-layered film 1 is formed so as to possess electrical conductivity of n-type. The lower layer 3 of the multi-layered film 1 is formed so as to possess electrical conductivity of p-type. The first layer 2 is arranged over the second layer 3, and the layers 2, 3 are connected with one another.

The material for photo-electric conversion can further have a substrate 4 which is located under the lower layer 3 of the multi-layered film 1 and supports the multi-layered film 1.

The upper layer 2 of the multi-layered diamond-like film 1 which possesses electrical conductivity of n-type can be composed of silicon with admixture of chrome. The lower layer 3 of the multi-layered diamond-like film 1 which possesses electrical conductivity of p-type can be composed of silicon with admixture of tungsten. The layers 2 and 3 have different crystallographic lattices. When they are connected with one another, an intermediate layer 5 is formed between the layers 2 and 3. It is composed of two intersection lattices of the layers 2 and 3. The substrate 4 under the multi-layered film 1 can be composed of silicon ceramics.

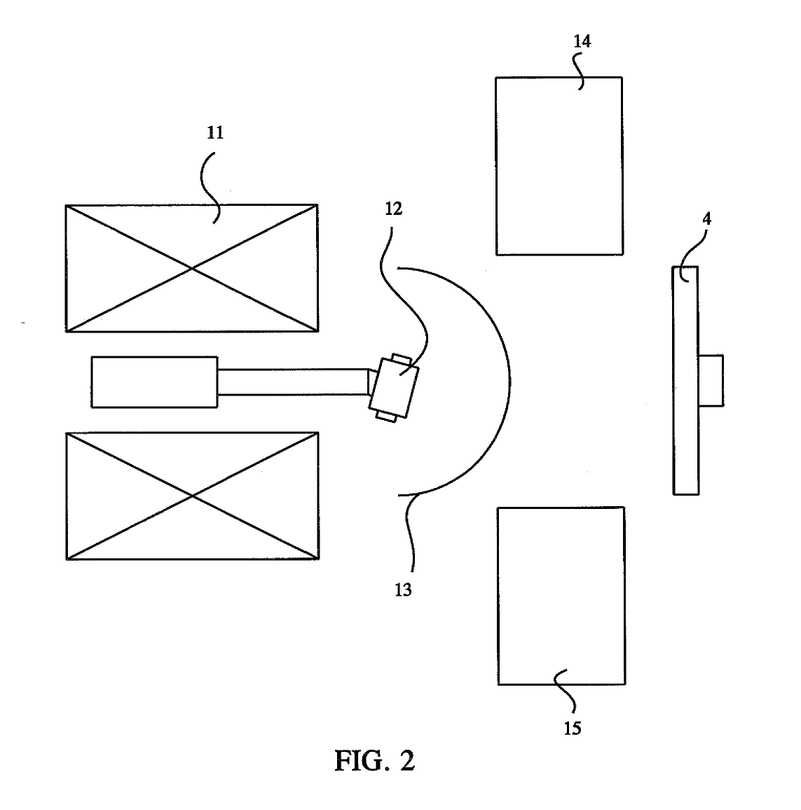

The method of manufacturing of the material for photo-electric conversion according to the present invention is illustrated in FIG. 2. This drawing shows a magnetic coil 11, a feeder 12, a cathode 13, a plasmatron 14 and a magnetron 15. The multi-layered film is grown in a horizontal direction. A magnetic field from the coil 11 pulls plasma created by a plasmatron to the substrate 4. A reactant which is a liquid silicon oil is supplied through the feeder 12 into a vacuum volume and is converted into a cloud. The cathode 13 coverts the cloud into a partially ionized plasma (2,000° C.). The plasma is fired by a potential between the cathode and the wall of the camera so that an arc is generated in almost fully ionized plasma, which is composed of carbon, hydrogen, silicon and a material of the cathode 13. The magnetic field pulls the content of the plasma towards the substrate 4.

For forming on the substrate 4 the second film 3, the cathode composed of tungsten is introduced into the apparatus. Ions of carbon reach the substrate and create on it starting formations of hydrogen and silicon with traces of tungsten. A powerful high frequency field is supplied onto the substrate so as to eliminate electrostatics and allow growth of film. Due to radiation the temperature of the substrate 4 can reach 250° C. The plasma is pulled towards the substrate and makes a feeding medium for growth of the second film 4.

For forming on the substrate 3 the second film 2, the cathode composed of chrome is introduced into the apparatus. Ions of carbon reach the substrate and create on it starting formations of hydrogen and silicon with traces of tchrome. A powerful high frequency field is again supplied onto the substrate so as to eliminate electrostatics and allow growth of film. The temperature of the substrate 4 can again reach 250° C. The plasma is pulled towards the substrate and makes a feeding medium for growth of the first film 2 over the second film 3.

The diamond-like semi-conducting film 1 is therefore produced on the substrate 4 by magnetron application of plasma with a chemical process in a vacuum from a liquid reactant—a silicon organic oil—in presence of high-frequency field. For providing electrical conductivity of the film, as explained above, alloying is used in the process of growing the film, in particular with such metals as tungsten, chrome, etc. from a target composed of corresponding elements.

The intermediate layer 5 of the film 1 is composed of two intersecting lattices, including the lattice of the layer 2 and the lattice of the layer 3. The alloying additive are located inside and provide the electrical conductivity. The film includes up to 90% of diamond-like phase. The nano-structure does not exceed several tenths of nm. The produced film 1 is a diamond-like film because it has properties which are typical for diamond, namely high micro hardness 10⁴ n/mm², high wear resistance, high resistance to aggressive media. When applied on a polished surface, its friction coefficient, depending on a load, is 0.03-0.1. The film has high adhesion to metals, ceramics, glass, polymeric materials, such as 120 kg/cm². The presence of hydrocarbon bonds imparts elasticity to the coating. The films have a broad range of specific resistances, with high resistance to super high densities of electric current—up to 10⁵ A/m.

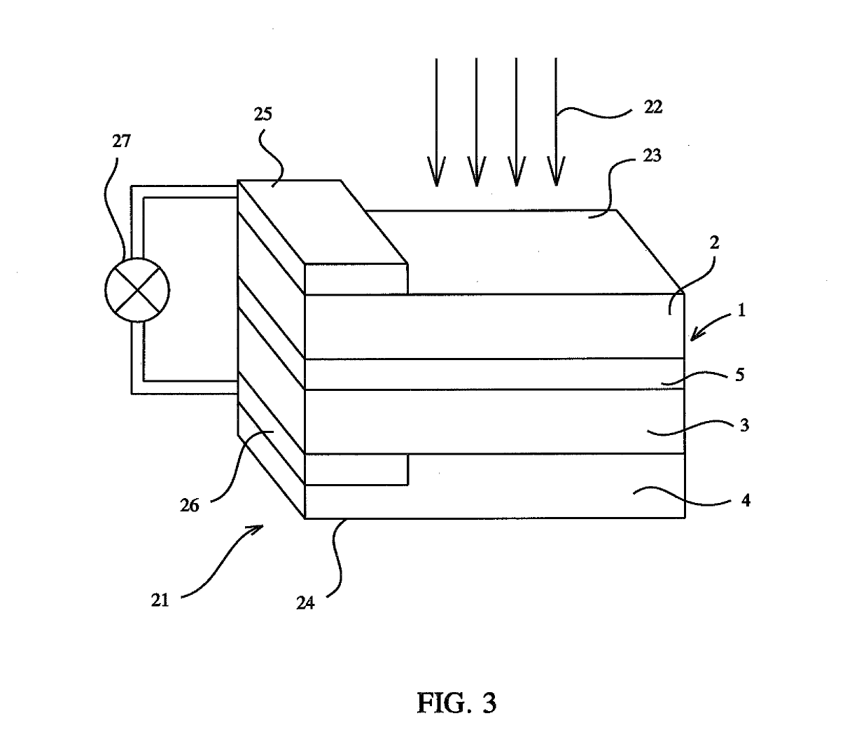

FIG. 3 shows a photo-electric converter according to the present invention, provided with the material for photo-electric conversion according to the present invention. The photo-electric converter identified as a whole with reference numeral 21 includes a material for photo-electric conversion of the present invention, formed as a multi-layered film 1, with an upper layer 2 possessing electrical conductivity of one type and a lower layer 3 possessing electrical conductivity of another different type. The upper layer 2 of the multi-layered diamond-like film 1 is formed so as to possess electrical conductivity of n-type. The lower layer 3 of the multi-layered diamond-like film 1 is formed so as to possess electrical conductivity of p-type. The intermediate layer 5 is located between the layers 2 and 3. The substrate 4 is located under the lower layer 3 of the multi-layered diamond-like film 1 and supports the multi-layered diamond-like film 1

The upper surface of the photo-electric converter according to the present invention, which is subjected to an action of light, for example solar light 22, is identified with reference numeral 23. The lower surface of the photo-electric converter according to the present invention is identified with reference numeral 24. An electrically conductive element, for example a negative electrode or contact 25 is provided on the upper surface, and another electrically conductive element, for example a positive electrode or contact 26 is provided on the lower surface of the photo-electric converter according to the present invention. The light applied to the upper surface of the photo-electric converter is converted into electric current which is then withdrawn from the photo-electric converter through the electrodes (contacts) and then through corresponding electrical energy transmission elements such wires, cables and the like to a consumer 27 for a corresponding use.

The present invention is not limited to the details shown since various modifications and structural changes are possible without departing from the main spirit of the invention.

What is desired to be protected by Letters Patent is set forth in particular in the appended claims:

1. A material for photo-electric conversion, comprising a multi-layered film including an upper layer possessing electrical conductivity of one type and a lower layer possessing electrical conductivity of another different type and applied on the upper layer.

2. The material for photo-electric conversion of claim 1, wherein the upper layer of the multi-layered film is formed so as to possess electrical conductivity of n-type and the lower layer of the multi-layered film is formed so as to possess electrical conductivity of p-type.

3. The material for photo-electric conversion of claim 1, further comprising a substrate located under the lower layer of the multi-layered film and supporting the latter.

4. The material for photo-electric conversion of claim 2, wherein the upper layer of the multi-layered film which possesses electrical conductivity of n-type is composed of silicon with alloying chrome admixture.

5. The material for photo-electric conversion of claim 2, wherein the lower layer of the multi-layered film which possesses electrical conductivity of p-type is composed of silicon with alloying tungsten admixture

6. The material for photo-electric conversion of claim 3, wherein the substrate of the multi-layered film is composed of silicon ceramics.

7. A photo-electric converter, comprising a material for photo-electric conversion, formed as a multi-layered film including an upper layer possessing electrical conductivity of one type and a lower layer possessing electrical conductivity of another different type.

8. The photo-electric convertor of claim 7, wherein the upper layer of the material for photo-electric conversion has an upper surface exposed to a source of light, the lower layer of the material for photo-electric conversion has a lower surface, and further comprising as substrate located under the lower surface and supporting the material for photo-electric conversion.

9. The photo-electric convertor of claim 7, wherein the layers are connected with electrical conductors which conduct to a consumer an electric current which is produced by the photo-electric converter.

10. The photo-electric convertor of claim 7, wherein the upper layer of the multi-layered diamond-like film is formed so as to possess electrical conductivity of n-type and the lower layer of the multi-layered diamond-like film is formed so as to possess electrical conductivity of p-type.

11. The photo-electric convertor of claim 7, wherein the upper layer of the multi-layered film which possesses electrical conductivity of n-type is composed of silicon with alloying chrome admixture.

12. The photo-electric convertor of claim 7, wherein the lower layer of the multi-layered film which possesses electrical conductivity of p-type is composed of silicon with tungsten alloying admixture.

13. The photo-electric conversion of claim 7, wherein the substrate of the multi-layered film is composed of silicon ceramics.
